(19) United States
(12) Patent Application Publication
(10) Pub. No.: US 2024/0093113 A1
(43) Pub. Date: Mar. 21, 2024

(54) SUBSTRATE COATED WITH A LUBRICANT COATING

(71) Applicants: Luxembourg Institute of Science and Technology, Esch-sur-Alzette (LU); CENTRE NATIONAL DE LA RECHERCHE SCIENTIFIQUE, PARIS (FR); INSTITUT NATIONAL des SCIENCES APPLIQUEES DE LYON, VILLEURBANNE (FR); Centre National d'Études Spatiales, PARIS (FR)

(72) Inventors: Jean-Baptiste CHEMIN, REDANGE (FR); Patrick CHOQUET, Longeville-Iés-Metz (FR); Guillaume COLAS, PIN (FR); Aurélien SAULOT, VILLEEURBANNE (FR); Michel YANN, MONJOIRE (FR)

(73) Assignee: Luxembourg Institute of Science and Technology, Esch-sur-Alzette (FR)

(21) Appl. No.: 18/524,555

(22) Filed: Nov. 30, 2023

Related U.S. Application Data
(63) Continuation of application No. PCT/FR2022/050999, filed on May 25, 2022.

(30) Foreign Application Priority Data
May 31, 2021 (FR) 21/05675

(51) Int. Cl. C10M 103/06; C01G 39/00; C23C 14/06; C23C 14/35

(52) U.S. Cl. CPC C10M 103/06; C01G 39/006; C23C 14/0623; C23C 14/352; C01P 2002/50; C10M 2201/066; C10N 2050/08

(57) ABSTRACT

The invention relates to a substrate coated with a coating consisting of molybdenum (Mo), sulfur (S), tantalum (Ta) and oxygen (O) atoms present in the form of one or several compound(s) selected from among the compounds of formula (I):

Mo_{w}SₓTa_{y}O_{z} (I)
wherein w is equal to 0 or 1; x varies from 0 to 2; y varies from 0 to 1 and z varies from 0 to 3; said coating comprising at least 5% at of oxygen and said coating having a dense compact microstructure.

### CROSS-REFERENCE TO RELATED APPLICATIONS

This application is a continuation of International Application No. PCT/FR2022/050999, filed on May 25, 2022, which claims priority to and the benefit of FR 21/05675, filed on May 31, 2021. The disclosures of the above applications are incorporated herein by reference.

### FIELD

The present disclosure relates to a substrate coated with a coating consisting of molybdenum (Mo), sulfur (S), tantalum (Ta) and oxygen (O) atoms having good lubricating properties in a vacuum atmosphere and an air atmosphere and a method for manufacturing said coated substrate. The present invention is particularly suited to the space industry, to the aeronautical industry, to biotechnology, to the chemical industry, to the medical industry and to the pharmaceutical industry.

### BACKGROUND

The statements in this section merely provide background information related to the present disclosure and may not constitute prior art.

It is known to use lubricant coatings consisting of molybdenum disulfide (MoS₂) to lubricate in particular components such as a bearing, a journal, gears or slides, and equipment such as scientific instruments, moving on land and in the space under vacuum. However, MoS₂ is very sensitive to moisture, which results in an accelerated wear and a premature breakage of the equipment and of the components in case of exposure and/or operation in humid atmospheres.

In order to overcome these drawbacks, it is known in particular during the storage of equipment on the ground or during tests, for example allowing verifying that a satellite is functional, so-called “Assembly, Integration, Testing” (AIT). This equipment is generally arranged in a closed enclosure, in particular a clean room. The atmosphere initially present in the clean room is evacuated by a stream of dry nitrogen and replaced by this same stream of dry nitrogen so that the hygrometric conditions of the enclosure become acceptable. Indeed, restrictive rules are applied to the AIT operations on satellites equipped with mechanisms lubricated by a MoS₂ coating. The white room standards involve a relative humidity level lower than 50-55%. This rate is nowadays difficult to control. Any overshoot causes the immediate stoppage of the AIT activities, which results in significant cost and delay.

However, rinsing under a stream of dry nitrogen requires a large manpower and should be carried out for a certain time to return to acceptable hygrometric conditions. The inactivity time, in particular in the aeronautical field, for the Assembly, Integration, Testing (AIT) of the satellites is non-negligible.

The rules associated with the use of a lubricant coating consisting of MoS₂ are expensive and complex to put in place. These rules are particularly restrictive, in particular for AIT activities.

There is a need to provide a coating allowing lubricating components and equipment in particular during the testing and storage phases. The lubrication thus carried out should prove to be resistant both to the ground during operation at atmospheric pressure as well as under vacuum, for example in space. Thus, there is a need to provide a lubricant coating whose properties remain intact in an air atmosphere and in a vacuum atmosphere thereby protecting the components and equipment from malfunctions such as those induced by wear and cracks.

During the last decades, numerous works have been carried out to provide a lubricant coating whose properties are not affected under an air atmosphere, that is to say a coating that could be used in a vacuum atmosphere and under an air atmosphere. However, some proposed lubricant coatings do not meet the requirements for large-scale industrialization or use and sometimes comprise toxic elements.

U.S. Pat. No. 6,423,419 discloses a molybdenum-sulfur coating deposited over a substrate and having a thickness of at least 200 nm and a substantially non-columnar homogeneous pore-less structure, the coating having a molybdenum-sulfur material and also having at least one other additional metal selected from among: titanium, zirconium, hafnium, tungsten, niobium, platinum, vanadium, tantalum, chromium, molybdenum and gold, incorporated up to 18% w/w. This coating has a Vickers hardness of at least 500 and is homogeneous and amorphous. U.S. Pat. No. 6,423,419 discloses several molybdenum-sulfur coatings wherein the additional metal is titanium.

In U.S. Pat. No. 6,423,419, the coating may be deposited by magnetron sputtering or by ion plating by Closed Field Unbalanced Magnetron Sputter Ion Plating (CFUBMSIP). During the deposition process, the polarization of the substrate may be supplied with direct current (DC), Radio Frequency or radiofrequency current (RF), alternative current (AC) or pulsed direct current (pulsed DC).

However, the coating disclosed in U.S. Pat. No. 6,423,419 does not allow obtaining good friction properties under vacuum. Moreover, the deposition method preferred in this document, namely CFUBMSIP, is complex to implement, does not allow obtaining coatings having good lubricating properties in all of the environments of interest related to the invention.

### SUMMARY

This section provides a general summary of the disclosure and is not a comprehensive disclosure of its full scope or all of its features.

The invention aims to overcome the aforementioned drawbacks by providing a coating enabling the lubrication of the components and the equipment moving on land and in the space, under an air atmosphere or under a vacuum atmosphere, the lubricating properties of which remain intact, thereby protecting said equipment or components. Moreover, the invention aims to provide a method for manufacturing this coating which is easy to implement and which ensures that said coating has good lubricating properties.

An object of the invention is a substrate coated with a coating consisting of molybdenum (Mo), sulfur (S), tantalum (Ta) and oxygen (O) atoms present in the form of one or several compound(s) selected from among the compounds of formula (I):

Mo_{w}SₓTa_{y}O_{z} (I)
wherein w is equal to 0 or 1; x varies from 0 to 2; y varies from 0 to 1 and z varies from 0 to 3; said coating comprising at least 5% at of oxygen and said coating having a dense compact microstructure.

Unlike the coatings of the prior art, the coating according to the invention offers good lubricating properties to lubricate the contact and protect the substrate from wear, and that being so both under an air atmosphere and under a vacuum atmosphere. Indeed, the Inventors have discovered that the compounds of formula (I), the minimum of oxygen as defined hereinabove as well as the microstructure of the coating allow offering a protection both under an air atmosphere and under a vacuum atmosphere. In particular, it seems that molybdenum and tantalum participate to the lubricating properties of the coating. Moreover, it also seems that unlike the prior art in which the presence of oxygen is reduced to minimum in order to avoid its presence in the coatings, the presence of oxygen in combination with tantalum in the coating forms an air protective barrier. The sensitivity of the coating to air, in particular to moisture, is significantly reduced, which allows ensuring slow wear and eliminating the risk of accelerated wear and premature breakage of the components and equipment. Thus, the rules related to the AIT activities are no longer necessary.

Further areas of applicability will become apparent from the description provided herein. It should be understood that the description and specific examples are intended for purposes of illustration only and are not intended to limit the scope of the present disclosure.

### DETAILED DESCRIPTION

The following description is merely exemplary in nature and is not intended to limit the present disclosure, application, or uses. It should be understood that throughout the drawings, corresponding reference numerals indicate like or corresponding parts and features.

In the present invention, the atomic percentage the abbreviation of which is “% at”. It is defined with respect to the total number of atoms in the coating.

The dense compact microstructure according to the invention corresponds to the Zone I of the Thornton diagram. In other words, it comprises columns tapering upwards with dome-shaped vertices.

Preferably, an object of the present invention is a substrate as defined before having the features described in the following embodiments, considered alone or in combination.

In one embodiment, the coating comprises more than 5%, advantageously at least 6% and preferably at least 10% and preferably at least 20% at of oxygen. Preferably, the coating comprises less than 35% at of oxygen. In this embodiment, the sensitivity of the coating to moisture is significantly reduced.

In one embodiment, the coating comprises more than 18% w/w of Ta. Preferably, the coating comprises at least 18.5% w/w, advantageously at least 19% w/w and for example between 19 and 30% w/w of Ta. For example, the coating comprises between 19 and 25% w/w of Ta. In this embodiment, the sensitivity of the coating to moisture in any type of environment is further reduced and the lubricating properties that prevent friction and wear of the coating are improved.

In one embodiment, in formula (I), x is equal to 0, 1, 2 or is a non-integer number comprised between 0 and 2; y is equal to 0, 1 or is a non-integer number comprised between 0 and 1; and z is equal to 0, 1, 2, 3 or is a non-integer number comprised between 0 and 3.

In one embodiment, in formula (I), at least 2 stoichiometric coefficients selected from among w, x, y and z are different from 0.

In one embodiment, the compounds of formula (I) comprising Mo are selected from among:

MoS₂Ta_{y}O_{z}

MoSₓTa_{y}O_{z}

and

MoSTa_{y}O

In this embodiment, the lubricating properties are improved and the coating is less sensitive to air.

In one embodiment, less than 60% at of the compounds of formula (I) comprising Mo have the formula:

MoS₂Ta_{y}O_{z}.

In one embodiment, the compounds comprising Ta have the formula (I):

Mo_{w}SₓTaO_{z}.

In one embodiment, the compounds of formula (I) comprising Ta have the formula (I):

Mo_{w}S₂TaO_{z}.

In this embodiment, the lubricating properties are improved and the coating is less sensitive to air.

In one embodiment, at least 19% w/w of the compounds of formula (I) comprising Ta have the formula:

Mo_{w}SₓTaO_{z}.

In one embodiment, the compounds of formula (I) comprising Ta comprise non-metallic Ta. In other words, the compounds of formula (I) comprising Ta do not comprise metal Ta0. Unlike the coatings of the prior art wherein the Ta is generally in a metallic form, it seems that the presence of Ta in a non-metallic form allows stabilizing the coating by making it less chemically sensitive to a wet environment, maximizing the lubricating performances by minimizing its reactivity with respect to the rubbing body, by preferably binding it to sulfur (S) and to oxygen (O) in particular in the form of tantalum sulfide (SₓTa_{y}), Tantalum oxysulfide and Tantalum oxide (SₓTaO_{z}). The non-metallic Ta is obtained during the co-deposition process, (1) the environment of the chamber contains oxygenated molecules (oxygen, water, carbon hydroxide) and (2) the MoS₂ sputtering deposition process from a MoS₂ target is known to render the MoS₂ slightly deficient in S which induces the presence of sulfur molecules in the deposition chamber and sites “active” on MoS₂ where sulfur has been removed. The idea of the invention consists in intentionally not cleaning the chamber of these pollutants, so that during spraying of the Ta from a pure Ta target, the Ta atoms in the plasma are very reactive and react with the oxygenated molecules, the sulfur molecules, and the active sites of the MoS₂. An assumption that can be formulated without binding the Applicant consists in considering that the Ta in the metallic form (the target) is modified into non-metallic Ta via the reactions during the transport of the Ta atoms from the target to the substrate, as well as reactions with oxygen and sulfur adsorbed at the surface of the substrate during deposition. This explains why the deposition under the conditions of the prior art which provides for cleaning the chamber in particular through the use of ‘Getter’ does not lead to the deposition of a non-metallic Ta.

In one embodiment, the coating is deposited directly over the substrate. In other words, no intermediate layer is deposited between the substrate and the coating. Indeed, it seems that the coating adheres to the substrate without it being necessary to add a layer, for example metallic, which promotes the adhesion of the coating onto the substrate.

In one embodiment, an intermediate layer is deposited over the substrate. In this embodiment, the substrate is coated with an intermediate layer, said intermediate layer being directly coated with a coating according to the invention. In this embodiment, depending on the nature of the substrate, the intermediate layer may be present to improve the adhesion of the coating onto the substrate.

In one embodiment, an intermediate layer is formed at the interface between the substrate and the coating; said intermediate layer results from the combination of the substrate and the coating during the process of manufacturing the substrate coated with said coating. Indeed, it seems that during the manufacturing process, the compounds of the coating and the substrate combine together so as to create an intermediate layer promoting the adhesion of the coating onto the substrate.

In one embodiment, the coating comprises no cubic boron nitride, titanium and/or aluminum. In this embodiment, it seems that there is a risk these compounds reducing the lubricating properties of the coating.

In one embodiment, the substrate is coated with one single coating layer. In other words, the coating is monolayer. In this embodiment, the Inventors have discovered that it is not necessary to deposit more than one coating layer to obtain the coating according to the invention.

In one embodiment, the coating is porous. In this embodiment, the coating may store more oxygen-rich molecules allowing facilitating lubrication.

In one embodiment, the microstructure of the coating is compact, dense and fibrous.

In one embodiment, the coating comprises unavoidable impurities resulting from the process such as carbon, water, argon or hydrocarbon molecules. For example, the coating comprises an amount smaller than 0.2% w/w of impurities.

In one embodiment, the substrate is metallic or non-metallic. In one embodiment, the metal substrate is selected from among: iron and its alloys, aluminum and its alloys, titanium and its alloys or copper and its alloys. In one embodiment, the non-metallic substrate is selected from among: glass, silicon, ceramic, carbon, composites comprising carbon or a polymer.

In one embodiment, the coating has a thickness smaller than or equal to 1.5 μm. Preferably, the coating has a thickness smaller than or equal to 1 μm.

Another object of the invention is a method for manufacturing the substrate coated with a coating according to the invention, the method comprising the following steps of: A. providing a substrate, B. the magnetron sputtering co-deposition of a first target comprising MoS₂, said first target being supplied with direct current or with radiofrequency current, and a second target comprising Ta, said second target being supplied with direct current optionally pulsed, wherein the co-deposition step B) is carried out under an atmosphere comprising an inert gas and oxygen.

The method according to the invention is easy to implement. Moreover, it does not require to be in a completely inert atmosphere. Indeed, the presence of oxygen is necessary to obtain the coating according to the invention having good lubricating properties which remain intact in an air atmosphere and under vacuum. Finally, the co-deposition by magnetron cathode sputtering of a first target comprising MoS₂, said first target being supplied with direct current or with radiofrequency current, and a second target comprising Ta, said second target being supplied with a direct current optionally pulsed allows obtaining the microstructure, the compounds of formula (I) and the presence of oxygen in the coating according to the invention. These conditions allow obtaining a dense fibrous structure offering numerous nanopores in which the oxygenated molecules could be trapped during the growth of the deposit, the parameters of the method are selected in particular in order to obtain a type I structure of the Thornton diagram.

In one embodiment, during step B), said first target is supplied with radiofrequency current, and said second target is supplied with pulsed direct current. In this embodiment, it seems that the compounds of formula (I) are formed more rapidly.

In one embodiment, during step B), the percentage of oxygen in the atmosphere is comprised between 0.1 and 5% by volume. Preferably, the percentage of oxygen in the atmosphere is comprised between 0.1 and 3% by volume. It seems that this percentage of oxygen in the atmosphere allows obtaining the minimum of oxygen present in the coating according to the invention.

In one embodiment, during step B), the substrate is heated up to a temperature comprised between 20 and 350° C. Preferably, during step B), the substrate is heated up to a temperature comprised between 50 and 150° C. In this embodiment, it seems that the formation of the compounds of formula (I) is promoted.

In one embodiment, during step B), a bias voltage comprised between −150 and 10V is applied to the substrate.

In one embodiment, during step B), the co-deposition is carried out under a pressure comprised between 2·10⁻³ mbar and 5·10⁻² mbar.

### Examples: Friction Coefficient Tests

AISI 440C grade steel substrates have been coated with coatings having a thickness of 1 μm deposited by magnetic sputtering.

The first coating consists of MoS₂ and is obtained by the Microslide process developed by VILAB AG. This coating is used in particular in the publication by Hartwig H., Engelhardt W., Schmidt R. (1995), Mechanism Qualification for Soho Sumer, Results and Lessons Learned. Proc. 6th Eur. Sp. Mech. Tribol. Symp., Zurich, Switzerland. The second coating consists of MoS₂ and tungsten carbide (WC). This coating is used in particular in the publication by J. I. Onate, M. Brizuela, J. L. Viviente, A. Garcia-Luis, I. Braceras, D. Gonzalez, I. Garmendia (2007), MoSₓ lubricant coatings produced by PVD technologies, Trans. IMF., vol. 85, pp. 75-81. The third coating, the trade name of which is “MoST™ coatings”, consists of MoS₂ and titanium. The fourth coating is the coating according to the invention.

The steel substrates have been disposed on a rotating support so as to rotate during the deposition of the coating. The percentage of oxygen in the atmosphere was 0.5% by volume. The substrate has been heated up to a temperature of 25° C. The voltage applied to the substrate was 0 V. The pressure was 5·10⁻³ mbar.

Afterwards, these coated substrates have been subjected to the friction test on a pin-on-plate tribometer, with alternating linear kinematics. In this test, a ball is held rigidly and brought into contact with the substrate under a force directed perpendicularly to the coated substrate. The coated substrate is set in linear motion and performs back-and-forth movements around its central position, thereby inducing pure sliding between the ball and the coating. The maximum Hertzian pressure in the contact was at most 1 G Pa. The sliding speed was 10 mm/s. The ball has performed 1,000 back-and-forth cycles on the different coated substrates. A new ball is used for each test.

First of all, the ball test has been carried out under a vacuum atmosphere having a pressure of 1·10⁻⁷ mbar.

The table hereinbelow combines the results of the friction coefficient tests.

TABLE 1

| | | Deposition | | Number of cycles | | | | | | | | | | |
|---|---|---|---|---|---|---|---|---|---|---|---|---|---|---|
| | | 1^{st} | 2^{nd} | 0 | 100 | 200 | 300 | 400 | 500 | 600 | 700 | 800 | 900 | 1000 |
| No. | Coatings | Target | Target | Friction coefficient | | | | | | | | | | |
| 1 | MoS₂, O % <5% | MoS₂ | — | 0.02 | 0.02 | 0.03 | 0.03 | 0.03 | 0.03 | 0.03 | 0.03 | 0.03 | 0.03 | 0.03 |
| | at. fibrous | | | | | | | | | | | | | |
| | compact dense | | | | | | | | | | | | | |
| | microstructure | | | | | | | | | | | | | |
| 2 | MoS₂ + WC, O % | MoS₂ | WC | 0.15 | 0.05 | 0.05 | 0.06 | 0.06 | 0.06 | 0.06 | 0.06 | 0.06 | 0.06 | 0.06 |
| | <3% at. compact | | | | | | | | | | | | | |
| | dense | | | | | | | | | | | | | |
| | microstructure | | | | | | | | | | | | | |
| 3 | MoS₂ + Ti, O % | MoS₂ | Ti | 0.03 | 0.02 | 0.02 | 0.12 | 0.42 | >0.5 | >0.5 | >0.5 | >0.5 | >0.5 | >0.5 |
| | <5% at. | | | | | | | | | | | | | |
| | compact dense | | | | | | | | | | | | | |
| | microstructure | | | | | | | | | | | | | |
| 4* | MoS_{0.5}Ta_{0.75}O_{0.75}(I) | MoS₂: | Ta: | 0.1 | 0.06 | 0.06 | 0.06 | 0.06 | 0.07 | 0.08 | 0.08 | 0.09 | 0.09 | 0.1 |
| | O = 30% at. | RF | DC | | | | | | | | | | | |
| | compact dense | | pulsed | | | | | | | | | | | |
| | microstructure | | | | | | | | | | | | | |

*according to the invention

The results show that the coating 4 according to the invention has a friction coefficient that is much lower than the coating 3. Moreover, the coatings 1, 2 and 4 have similar friction coefficients.

Secondly, the coated substrates have been subjected afterwards to the pin-on-plate friction test, with alternating linear kinematics, under a humid air atmosphere and then a vacuum atmosphere having a pressure of 1·10⁻⁷ mbar, 150 back-and-forth friction cycles under the humid air atmosphere and then 850 back-and-forth friction cycles under the vacuum atmosphere have been performed. The table hereinbelow combines the results of the friction coefficient tests.

TABLE 2

| | | Number of cycles | | | | | | | | | | |
|---|---|---|---|---|---|---|---|---|---|---|---|---|
| | | 0 | 100 | 200 | 300 | 400 | 500 | 600 | 700 | 800 | 900 | 1000 |
| No. | Coatings | Friction coefficient | | | | | | | | | | |
| 1 | MoS₂, O % <5% | 0.12 | 0.17 | 0.06 | 0.06 | 0.06 | 0.06 | 0.06 | 0.07 | 0.08 | 0.08 | 0.08 |
| | at. fibrous | | | | | | | | | | | |
| | compact dense | | | | | | | | | | | |
| | microstructure | | | | | | | | | | | |
| 2 | MoS₂ + WC, O % | 0.32 | 0.16 | 0.07 | 0.3 | — | — | — | — | — | — | — |
| | <3% at. | | | | | | | | | | | |
| | compact dense | | | | | | | | | | | |
| | microstructure | | | | | | | | | | | |
| 3 | MoS₂ + Ti, O % | 0.06 | 0.12 | 0.04 | 0.04 | 0.12 | 0.45 | >0.5 | >0.5 | >0.5 | >0.5 | >0.5 |
| | <5% at. | | | | | | | | | | | |
| | compact dense | | | | | | | | | | | |
| | microstructure | | | | | | | | | | | |
| 4* | MoS_{0.5}Ta_{0.75}O_{0.75}(I) | 0.09 | 0.13 | 0.04 | 0.04 | 0.03 | 0.03 | 0.03 | 0.03 | 0.04 | 0.04 | 0.04 |
| | O = 30% at. | | | | | | | | | | | |
| | compact dense | | | | | | | | | | | |
| | microstructure | | | | | | | | | | | |

*according to the invention

The results show that the coating 4 according to the invention has a friction coefficient that is much lower than the coatings 1, 2 and 3.

Thus, the coating according to the invention offers good lubricating properties under a humid air atmosphere or a vacuum atmosphere. Moreover, the coating according to the invention keeps its good lubricating properties following the passage of a humid air atmosphere, at atmospheric pressure, into an atmosphere under ultra-vacuum. Thus, any premature degradation of the lubricating behavior is inhibited upon an atmosphere change.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A substrate coated with a coating consisting of molybdenum (Mo), sulfur (S), tantalum (Ta) and oxygen (O) atoms present in the form of one or several compound(s) selected from among the compounds of formula (I):
Mo_{w}SₓTa_{y}O_{z} (I),
wherein w is equal to 0 or 1; x varies from 0 to 2; y varies from 0 to 1 and z varies from 0 to 3; said coating comprising at least 5% at of oxygen and said coating having a dense compact microstructure.

2. The substrate according to claim 1, wherein in formula (I), x is equal to 0, 1, 2 or is a non-integer number comprised between 0 and 2; y is equal to 0, 1 or is a non-integer number comprised between 0 and 1; and z is equal to 0, 1, 2, 3 or is a non-integer number comprised between 0 and 3.

3. The substrate according to claim 1, wherein in formula (I), at least 2 stoichiometric coefficients selected from among w, x, y, and z are different from 0.

4. The substrate according to claim 1, wherein the coating comprises more than 18% w/w of Ta.

5. The substrate according to claim 1, wherein the compounds of formula (I) comprising Mo are selected from among:
MoS₂Ta_{y}O_{z},
MoSₓTa_{y}O_{z},
and
MoSTa_{y}O.

6. The substrate according to claim 1, wherein less than 60 at % of the compounds of formula (I) comprising Mo have the formula:
MoS₂Ta_{y}O_{z}.

7. The substrate according to claim 1, wherein the compounds comprising Ta have the formula (I):
Mo_{w}SₓTaO_{z}.

8. The substrate according to claim 1, wherein at least 19% w/w of the compounds of formula (I) comprising Ta have the formula:
Mo_{w}SₓTaO_{z}.

9. The substrate according to claim 1, wherein the compounds of formula (I) comprising Ta comprise non-metallic Ta.

10. A method for manufacturing the coated substrate according to claim 1, the method comprising the following steps of:
A. providing a substrate,
B. the magnetron sputtering co-deposition of a first target comprising MoS₂, said first target being supplied with direct current or with radiofrequency current, and a second target comprising Ta, said second target being supplied with direct current optionally pulsed,
wherein the co-deposition step B) is carried out under an atmosphere comprising an inert gas and oxygen.

11. The manufacturing method according to claim 10, wherein during step B), the percentage of oxygen in the atmosphere is comprised between 0.1 and 5% by volume.

12. The manufacturing method according to claim 10, wherein during step B), the substrate is heated up to a temperature comprised between 20° C. and 350° C.
